(19) United States
(12) Patent Application Publication
(10) Pub. No.: US 2005/0048779 A1
(43) Pub. Date: Mar. 3, 2005

(54) Semiconductor device and method of manufacturing the same

(76) Inventor: Takayuki Ito, Kawasaki-shi (JP)

Correspondence Address: Finnegan, Henderson, Farabow,;Garrett & Dunner, L.L.P., 1300 I Street, N.W., Washington, DC, 20005-3315, US

(21) Appl. No.: 10/694,046

(22) Filed: Oct. 28, 2003

(30) Foreign Application Priority Data
Aug. 29, 2003 (JP) 2003-209618

(51) Int. Cl. H01L 21/302; H01L 21/461

(52) U.S. Cl. 438/689

(57) ABSTRACT

There is disclosed a method of manufacturing a semiconductor device, comprising entirely implanting electrically inactive first impurity to one main surface of a semiconductor substrate, and carrying out heat treatment by light with respect to the semiconductor substrate to which the first impurity is implanted.

### CROSS-REFERENCE TO RELATED APPLICATIONS

This application is based upon and claims the benefit of priority from the prior Japanese Patent Application No. 2003-209618, filed Aug. 29, 2003, the entire contents of which are incorporated herein by reference.

### BACKGROUND OF THE INVENTION

1. Field of the Invention

The present invention relates to a semiconductor device including a semiconductor substrate subjected to heat treatment, and to a method of manufacturing the same. In particular, the present invention relates to a semiconductor device including a semiconductor substrate whose surface layer is formed with impurity diffusion regions by heat treatment, and to a method of manufacturing the same.

2. Description of the Related Art

LSI performance is improved by enhancing the integration level, that is, by micro-fabricating elements forming the semiconductor. Recently, integrated circuits are made into large scale more and more, and with the large scale, technique of micro-fabricating elements has been remarkably developed. With the scale down of element dimension, it is more significant to form shallow p-n junction.

The following method of forming shallow impurity diffusion regions is given in general. More specifically, predetermined ions are implanted into a silicon (Si) substrate using low acceleration energy. Thereafter, optimized annealing process is carried out with respect to the Si substrate. The technique described above has been disclosed in JPN. PAT. APPLN. KOKAI Publications No. 2002-141298, 2002-246328, 2002-198322, 2002-175772, Hei 10-26772, U.S. Pat. No. 6,417,515, etc.

Boron (B) functioning as a p-type dopant or phosphorus (P) and arsenic (As) functioning as an n-type dopant are generally used for ion implantation. However, these boron (B) or phosphorus (P) and arsenic (As) have large diffusion coefficient in the Si substrate. For this reason, these impurities are diffused inwardly and outwardly in the Si substrate even if the following rapid thermal annealing (RTA) process is employed as heat treatment for activating impurities. According to the rapid thermal annealing, time spent for annealing is short, and a halogen lamp is used. As a result, it is difficult to obtain desired distribution profile in ion-implanted impurities. If the annealing temperature is reduced in order to prevent impurity diffusion, the problem arises such that the ratio of activating impurity greatly reduces. As seen from the above description, according to the normal RTA process, it is difficult to form a shallow low-resistance diffusion layer having a junction depth of 20 nm or less.

In order to solve the problem, laser annealing and flash lamp annealing have been recently studied as the process of instantaneously supplying energy necessary for activating impurity. However, laser beam is excellent in directivity; for this reason, interference is easy to occur, and also, irradiation area is restricted. As a result, it is difficult to keep uniformity and reproducibility of irradiation energy with respect to wafer (substrate) having large area. In addition, it is difficult to control the intensity of the laser beam; for this reason, it is difficult to obtain the intensity suitable for annealing. As a result, energy density per unit time or unit area becomes too high; for this reason, there is a possibility that the surface of the semiconductor substrate is melted. As seen from the explanation, the normal laser annealing process has a possibility of causing morphological degradation on the surface of the semiconductor substrate after impurity activation process.

On the other hand, according to flash lamp annealing process recently attracting interests, the light emission of heat source, that is, Xenon flash lamp completes in very short time such as several 100 μm sec to several m sec. This serves to activate impurity ions without changing the distribution of impurity ions implanted into a semiconductor layer. In addition, heat treatment is collectively carried out with respect to the entire surface of the semiconductor substrate having large area; therefore, throughput is high. However, according to the flash lamp annealing process, there is a possibility that great thermal stress is applied to the semiconductor substrate. This is because the flash lamp has wide irradiation area and controls the rise and fall of temperature at high speed. In particular, wafer surface is formed with patterns consisting of several kinds of films such as poly-Si, SiO₂ and SiN. In this case, heat non-uniformity is easily generated between these several kinds of films. If the heat non-uniformity is generated, damages such as dislocation and defect are easy to occur in the wafer. This is a factor of readily reducing the production yield. In such a case, substrate pre-heating temperature or irradiation energy of the flash lamp is reduced, and thereby, it is possible to prevent damages to the substrate. However, impurities are not sufficiently activated. As described above, according to the normal flash lamp annealing process, it is a problem that process window (process margin) is narrow in the manufacture process of semiconductor elements.

As seen from the explanation, if the surface layer of the substrate is formed with impurity diffusion layers, there is a possibility that various problems arise in the substrate regardless of heat treatment processes. In particular, deformation and damages by thermal stress are generated in the substrate, and the quality of substrate is reduced by heat non-uniformity. The foregoing problems possibly arise in carrying out heat treatment with respect to the substrate as well as the case of forming impurity diffusion layers in the substrate.

### BRIEF SUMMARY OF THE INVENTION

According to an aspect of the invention, there is provided a method of manufacturing a semiconductor device, comprising: entirely implanting electrically inactive first impurity to one main surface of a semiconductor substrate; and carrying out heat treatment by light with respect to the semiconductor substrate to which the first impurity is implanted.

According to an another aspect of the invention, there is provided a method of manufacturing a semiconductor device, comprising: providing a gate electrode having a gate insulating film on one main surface of a semiconductor substrate; entirely implanting electrically inactive first impurity to one main surface of the semiconductor substrate provided with the gate electrode while implanting electrically active second impurity having predetermined conduction type to the semiconductor substrate to a region adjacent to the gate electrode of the semiconductor substrate using the gate electrode as a mask; forming shallow source/drain diffusion regions having the predetermined conduction type, the shallow source/drain diffusion regions being formed in a manner that heating treatment using light is carried out the semiconductor substrate to which the first and second impurities are implanted, and thereby, the second impurity is activated; providing a gate sidewall film around the gate electrode; entirely implanting the first impurity to one main surface of the semiconductor substrate provided with the gate sidewall film while implanting the second impurity to the semiconductor substrate to a region adjacent to the gate sidewall film of the semiconductor substrate using the gate electrode and the gate sidewall film as a mask; and forming deep source/drain diffusion regions having the predetermined conduction type, and continuing with the shallow source/drain diffusion regions, the deep source/drain diffusion regions being formed in a manner that the heating treatment is carried out the semiconductor substrate to which the first and second impurities are implanted, and thereby, the second impurity is activated.

According to still another aspect of the invention, there is provided a semiconductor device comprising: a semiconductor substrate subjected to heat treatment using light after electrically inactive first impurity is entirely implanted.

According to yet another aspect of the invention, there is provided a semiconductor device comprising: a semiconductor substrate formed with source/drain diffusion regions having predetermined conduction type, and the semiconductor substrate being subjected to the following treatment such that electrically inactive first impurity is entirely implanted to the semiconductor substrate while electrically active second impurity having predetermined conduction type being implanted thereto, and the source/drain diffusion regions being formed in a manner that heating treatment using light is carried out the semiconductor substrate to which the first and second impurities are implanted, and thereby, the second impurity is activated; and a gate electrode provided on the source/drain diffusion regions, and having a gate insulating film and a gate sidewall film.

### BRIEF DESCRIPTION OF THE SEVERAL VIEWS OF THE DRAWING

FIG. 1A to FIG. 1C are cross-sectional views showing a process of a manufacturing method of a semiconductor device according to one embodiment of the present invention;

FIG. 2A to FIG. 2C are cross-sectional views showing a process of a manufacturing method of a semiconductor device according to one embodiment;

FIG. 3A to FIG. 3D are cross-sectional views showing a process of a manufacturing method of a semiconductor device according to one embodiment;

FIG. 4 is a TEM photograph showing the cross section of a silicon substrate given as a comparative example subjected to heat treatment according to a conventional technique;

FIG. 5 is a graph showing a proper process condition according to one embodiment in the relationship substrate pre-heating temperature and irradiation energy density of a flash lamp; and

FIG. 6 is a graph showing a proper process condition according to the comparative example in the relationship substrate pre-heating temperature and irradiation energy density of a flash lamp.

### DETAILED DESCRIPTION OF THE INVENTION

One embodiment of the present invention will be described below with reference to the accompanying drawings.

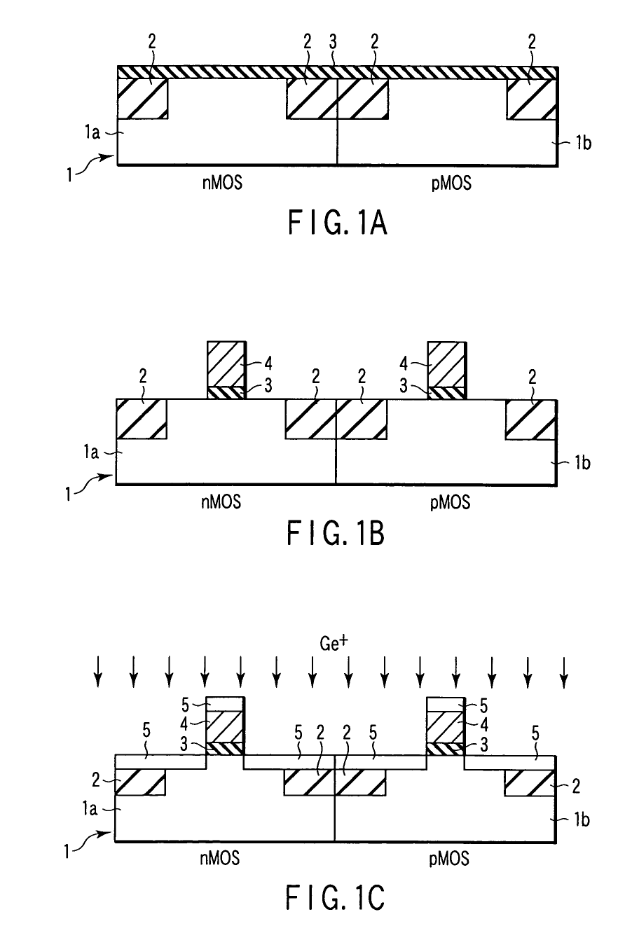

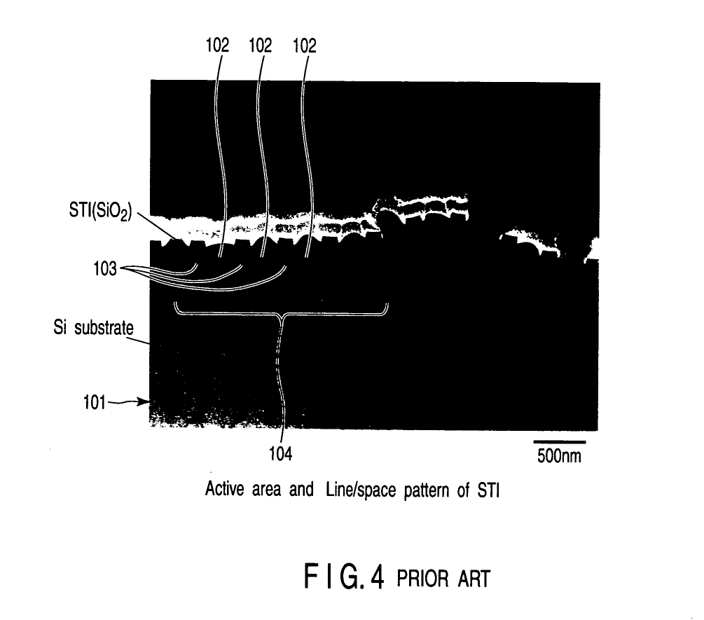

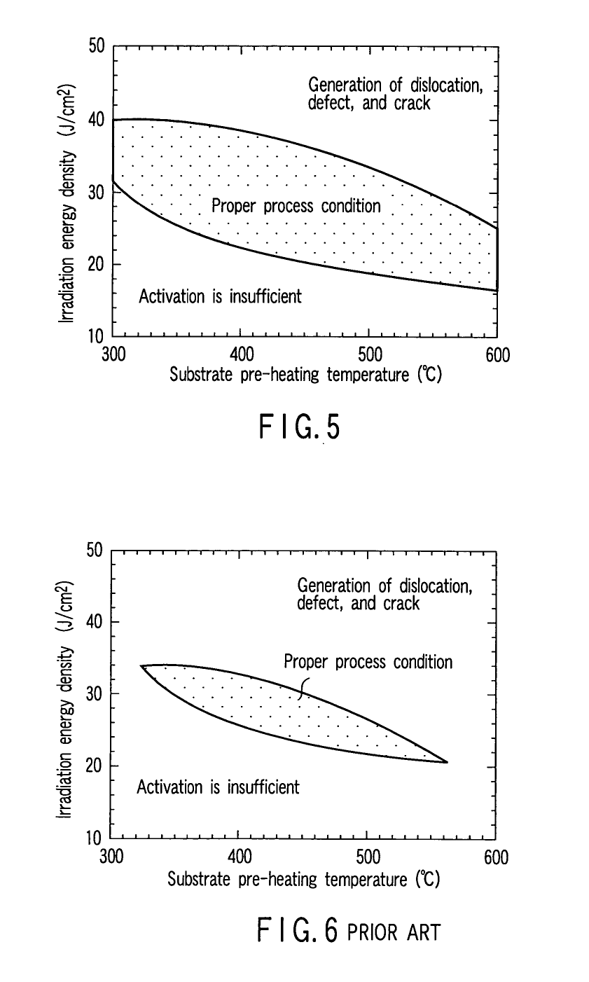

FIG. 1A to FIG. 3D are process cross-sectional views showing a process of a manufacturing method of a semiconductor device according to one embodiment of the present invention. FIG. 4 is a TEM photograph showing the cross section of a silicon substrate given as a comparative example subjected to heat treatment according to a conventional technique. FIG. 5 is a graph showing a proper process condition according to one embodiment in the relationship substrate pre-heating temperature and irradiation energy density of a flash lamp. FIG. 6 is a graph showing a proper process condition according to the comparative example in the relationship substrate pre-heating temperature and irradiation energy density of a flash lamp.

In the embodiment, electrically inactive impurities are ion-implanted into the entire surface of a semiconductor substrate at least one time before heat treatment by radiant energy is carried out with respect to the semiconductor substrate. In this case, at least one of group IV-B elements such as C, Si, Ge, Sn and Pb is used as the electrically inactive impurity. By doing so, it is possible to prevent damages such as dislocation, defect and morphological degradation in the semiconductor substrate. The following is a detailed description on the case of manufacturing a CMOS transistor on the semiconductor substrate.

As shown in FIG. 1A, p-well and n-well layers (both are not shown) are formed respectively on nMOS and pMOS regions 1a and 1b of a semiconductor substrate (silicon substrate) 1 according to the normal manufacturing method of CMOS transistor. These NMOS and pMOS regions 1a and 1b are formed with isolation regions 2. Thereafter, a gate insulating film 3 comprising a silicon oxide film (SiO₂ film) is provided to coat the surface of the silicon substrate (Si substrate) 1 formed with the isolation regions 2.

As illustrated in FIG. 1B, a polysilicon film 4 functioning as a gate electrode is deposited on predetermined positions on the gate insulating film 3. The gate electrode 4 and the gate insulating film 3 are selectively processed by RIE to be formed into a predetermined shape. By doing so, the gate electrode 4 is formed one by one on nMOS and pMOS regions 1a and 1b of the silicon substrate 1.

As depicted in FIG. 1C, electrically inactive first impurity, that is, germanium (Ge) is entirely ion-implanted into the upper portion of each gate electrode 4 and the surface layer of the silicon substrate 1. The foregoing substance, that is, germanium (Ge) has almost no influence to the conduction type and conductivity of the silicon substrate 1. In this case, germanium ion (Ge⁺) is implanted under the conditions that the acceleration energy is set to about 1 KeV and the dosage is set to about 5×10¹⁴ cm⁻². In addition, the concentration of the implanted germanium is set to 1×10¹⁹ cm⁻³. By doing so, the upper portion of each gate electrode 4 and the surface layer of the silicon substrate 1 are formed with a first Ge implantation region 5.

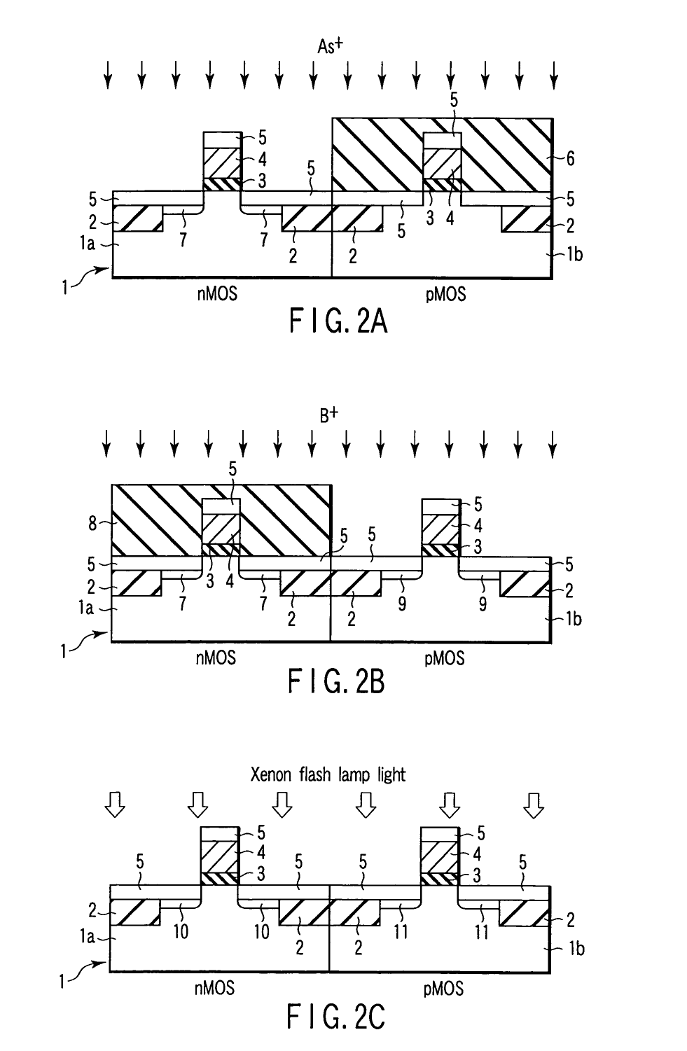

As shown in FIG. 2A, a resist film 6 is deposited to cover the pMOS region 1b formed with a Ge implantation region 5 and the gate electrode on the region 1b. The second impurity, that is, arsenic (As) used as n-type impurity is ion-implanted into the surface layer of the nMOS region 1a of the silicon substrate 1 using the gate electrode 4 on the nMOS region 1a formed with the Ge implantation region 5. In this case, arsenic ion (As⁺) is implanted under the conditions that the acceleration energy is set to about 1 KeV and the dosage is set to about 1×10¹⁵ cm⁻². According to the foregoing ion implantation, the surface layer of the nMOS region 1a adjacent to the gate electrode 4 is formed with shallow n-type impurity regions 7 containing arsenic (As). Thereafter, the resist film 6 on the pMOS region 1b is removed by etching.

As illustrated in FIG. 2B, a resist film 8 is deposited to cover the nMOS region 1a formed with formed with shallow n-type impurity regions 7 containing n-type impurity on the surface layer and the gate electrode on the region 1a. The second impurity, that is, boron (B) used as p-type impurity is ion-implanted into the surface layer of the pMOS region 1b of the silicon substrate 1 using the gate electrode 4 on the pMOS region 1b formed with the Ge implantation region 5. In this case, boron ion (B+) is implanted under the conditions that the acceleration energy is set to about 0.2 KeV and the dosage is set to about 1×10¹⁵ cm⁻². According to the foregoing ion implantation, the surface layer of the pMOS region 1b adjacent to the gate electrode 4 is formed with shallow p-type impurity regions 9 containing boron (B). Thereafter, the resist film 8 on the nMOS region 1a is removed by etching.

As depicted in FIG. 2C, light from xenon (Xe) flash lamp (not shown) is irradiated to the silicon substrate 1 and the surface of each electrode in a state that the silicon substrate 1 is previously heated to about 400° C. (substrate pre-heating). By doing so, annealing is subjected to the silicon substrate 1 and the like. Annealing is carried out, and thereby, n-type impurity (As) and p-type impurity (B) ion-implanted to each surface layer of nMOS and pMOS regions 1a and 1b are individually activated. In addition, crystal defect is repaired in shallow impurity regions 7 and 9 at each surface layer of rMOS and pMOS regions 1a and 1b. As a result, shallow n-type source/drain diffusion layer (extension region) 10 adjacent to the gate electrode is formed at the surface layer of the NMOS region 1a. On the other hand, shallow p-type source/drain diffusion layer 11 adjacent to the gate electrode is formed at the surface layer of the pMOS region 1b. In the embodiment, the above-mentioned substrate pre-heating is carried out using a hot plate (not shown).

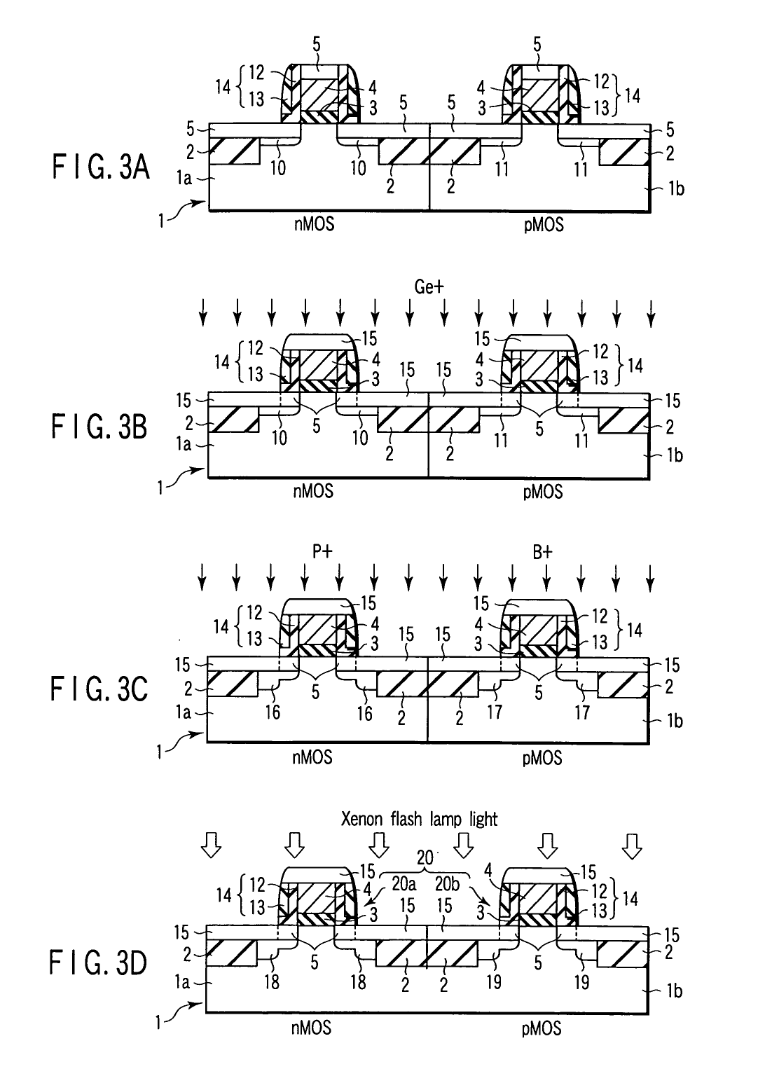

As shown in FIG. 3A, the following silicon films are successively deposited by CVD. Namely, silicon nitride film (SiN film) 12 and silicon oxide film (SiO₂ film) 13 are deposited to cover the silicon substrate 1 formed with shallow source/drain diffusion layers 10 and 11 and the surface of each gate electrode 4. RIE is carried out so that SiN film 12 and SiO₂ film 13 can be selectively left at only vicinity of the side of each gate electrode. By doing so, a sidewall spacer (gate sidewall film) 14 comprising two-layer structure of SiN film 12 and SiO₂ film 13 is provided to cover the side of each gate electrode 4.

As illustrated in FIG. 3B, germanium (Ge) is entirely ion-implanted to the upper portion of each gate electrode 4 formed with the sidewall spacer 14 and the surface layer of the silicon substrate 1. In this case, germanium ion (Ge+) is implanted under the conditions that the acceleration energy is set to about 1 KeV and the dosage is set to about 5×10¹⁴ cm⁻². In addition, the concentration of the implanted germanium is set to 1×10¹⁹ cm⁻³. By doing so, the upper portion of each gate electrode 4 and the surface layer of the silicon substrate 1 are formed with a second Ge implantation region 15.

As depicted in FIG. 3C, a third impurity is ion-implanted to each surface layer of nMOS and pMOS regions 1a and 1b of the silicon substrate 1 formed with the second Ge implantation region 15, using each gate electrode 4 and the sidewall spacer 14. More specifically, phosphorus (P) used as n-type impurity is ion-implanted to the NMOS region 1a. In this case, phosphorus ion (P⁺) is implanted under the conditions that the acceleration energy is set to about 15 KeV and the dosage is set to about 5×10¹⁵ cm⁻². According to the foregoing ion implantation, deep n-type impurity regions 16 containing P are formed at the position separating from the end of the gate electrode 4 on the surface layer of the nMOS region 1a. In addition, according to the ion implantation, P is ion-implanted to the upper portion of the gate electrode 4 and the sidewall spacer 14 on the nMOS region 1a.

On the other hand, boron (B) used as p-type impurity is ion-implanted to the pMOS region 1b. In this case, boron ion (B⁺) is implanted under the conditions that the acceleration energy is set to about 4 KeV and the dosage is set to about 5×10¹⁵ cm⁻². According to the foregoing ion implantation, deep p-type impurity regions 17 containing B are formed at the position separating from the end of the gate electrode 4 on the surface layer of the pMOS region 1b. In addition, according to the ion implantation, B is ion-implanted to the upper portion of the gate electrode 4 and the sidewall spacer 14 on the pMOS region 1b.

As seen from FIG. 3D, light from xenon (Xe) flash lamp (not shown) is irradiated to the silicon substrate 1 and the surface of each electrode in a state that the silicon substrate 1 is previously heated to about 400° C. (substrate pre-heating). By doing so, annealing is subjected to the silicon substrate 1 and the like. In this case, the annealing conditions are set as follows. Light emitting time (irradiation time), that is, the pulse width of the Xe flash lamp is set to about 1 ms, and irradiation energy density is set to about 35 J/cm². Annealing is carried out, and thereby, n-type impurity (P) and p-type impurity (B) ion-implanted to each surface layer of nMOS and pMOS regions 1a and 1b are individually activated. In addition, internal crystal defect is repaired in deep n-type and p-type impurity regions 16 and 17 at each surface layer of nMOS and pMOS regions 1a and 1b. As a result, deep n-type source/drain diffusion layers 18 are formed at the position separating from the end of the gate electrode 4 on the surface layer of the NMOS region 1a. On the other hand, deep p-type source/drain diffusion layers 19 are formed at the position separating from the end of the gate electrode 4 on the surface layer of the PMOS region 1b. In the embodiment, the above-mentioned substrate pre-heating is carried out using a hot plate (not shown).

Hereinafter, the following process is carried out although no illustration and details are omitted. According to atmospheric-pressure CVD, silicon oxide film (SiO₂ film) functioning as interlayer insulating film is entirely formed on the surface of the silicon substrate 1 to cover each gate electrode 4 under the condition that deposition temperature is set to 400° C. Thereafter, contact holes (not shown) are opened at predetermined portions in the silicon oxide film, and source/drain electrodes and interconnects are formed. By doing so, a desired CMOS transistor 20 comprising an nMOS transistor 20a and a pMOS transistor 20b is obtained. Thereafter, a desired semiconductor device comprising the CMOS transistor 20 is obtained via predetermined process.

The following is a description on the comparison between semiconductor substrates subjected to heat treatment according to the embodiment and the conventional technique. The semiconductor substrate (silicon substrate) given as the comparative example differs from the above-mentioned embodiment in the following points. The ion implantation process of group IV-B elements such as Ge shown in FIG. 1C and FIG. 3B is not carried out. Impurities As, B and P are ion-implanted, and thereafter, light beam from the Xe flash lamp is immediately irradiated under the same conditions as the embodiment.

FIG. 4 shows a cross section of a silicon substrate 101 given as the comparative sample, that is, a photograph observed by differential interference microscope and Transmission Electron Microscope (TEM). In this case, no illustration of the cross section is shown. The surface layer of the silicon substrate 101 is formed with a line/space pattern comprising an active area 102, and a Shallow Trench Isolation (STI) area in which silicon oxide film (SiO₂ film) 103 is buried. As seen from the photograph shown in FIG. 4, the silicon substrate 101 receives various damages such as dislocation, stacking fault and degradation of surface flatness by fusion. On the contrary, the semiconductor substrate (silicon substrate) 1 of the embodiment has no damages shown in the silicon substrate 101 of the comparative sample according to the observation by inventors. In this case, the illustration of the substrate 1 is omitted.

FIG. 5 shows proper process conditions (process window) in the relationship between substrate pre-heating temperature and irradiation energy density of flash lamp in the embodiment. FIG. 6 shows proper process conditions (process window) in the relationship between substrate pre-heating temperature and irradiation energy density of flash lamp in the comparative example. As seen from FIG. 5 and FIG. 6, with an increase of the pre-heating temperature, the irradiation energy density required for activating impurities is gradually reduced in both embodiment and comparative example. However, with an increase of the pre-heating temperature, the irradiation energy density dislocation on which defect or crack is generated in the substrate becomes small. In other words, with an increase of the pre-heating temperature, the substrate is easy to receive damages in both embodiment and comparative example.

As is evident from FIG. 5 and FIG. 6, according to the present embodiment, process window is wider than the comparative example, and process margin is large. In other words, according to the embodiment, the substrate is hard to receive damages as compared with the comparative example, and impurities are easy to be activated. In addition, the inventors conducted an experiment in surface uniformity of the silicon substrate. According to the experiment, variations of diffusion layer resistance were large in the comparative example, and standard deviation/means value×100%: σ was about 10%. On the contrary, σ was reduced to 1% or less in the present embodiment. The reason will be described below in detail.

The Xenon flash lamp is a white-light lamp, which has a visible light range of wavelength shorter than silicon (Si) absorption end as the main light-emitting range (peak wavelength range: about 300 to 500 nm). In addition, the Xenon flash lamp can perform high-speed temperature rise/fall in millimeter-second order. Thus, heating efficiency by the Xenon flash lamp greatly depends on the substrate surface state, that is, material quality (optical absorption coefficient) of the substrate and film deposited thereon. In the comparative example described above, the following films exist on the Si substrate 101 consisting of single crystal silicon (Si). The films are SiO₂ film 103 forming the isolation region 104, poly-Si layer (not shown) functioning as gate electrode, SiO₂ and SiN films forming the sidewall spacer of the gate electrode. For this reason, the surface state on the Si substrate and optical absorption coefficient differs in places. If flash lamp annealing is carried out under such conditions, local temperature non-uniformity occurs between materials having different quality; as a result, thermal stress is locally generated. The SiO₂ film 103 shows lens effect by the difference in refractive index between Si substrate 101 and SiO₂ film 103 forming the isolation region 104. For this reason, there is a possibility of locally heating the Si substrate 101. As seen from the reason described above, the Si substrate 101 of the comparative example is easy to receive damages such as dislocation and stacking fault.

On the contrary, in the embodiment, Ge is ion-implanted to the entire surface of the Si substrate 1 before flash lamp annealing is carried out. By doing so, the surface optical absorption coefficient is made approximately uniform between different materials, and the difference in heating efficiency is offset. In addition, the difference in refractive index is offset between Si and SiO₂, so that local heating can be prevented. These effects described above serve to improve uniformity of thermal characteristic on the surface of the Si substrate, and to prevent the generation of thermal stress by temperature difference between different materials. As described above, Ge is ion-implanted to the surface of the Si substrate 1, and thereby, optical absorption increases. As a result, impurities implanted to extension regions 10, 11 and source/drain regions 18, 19 are effectively activated. By doing so, it is possible to reduce irradiation energy necessary for activating impurities. In addition, the possibility of generating thermal stress in the Si substrate 1 is reduced, so that production yield can be improved. High-quality shallow and deep source/drain diffusion layers 10, 11 and 18, 19 are effectively and readily formed. Therefore, it is possible to provide the CMOS transistor 20 having improved quality and reliability.

In laser annealing process, the following technique has been conventionally known in order to make uniform absorption of light source energy in the substrate without giving damages to the substrate. According to the technique, optical absorption films such as poly-Si film, Ti film or TiN film are formed on the substrate although illustration is omitted. However, according to the technique, optical absorption films absorb energy once irradiated from light source, and thereafter, front-end film or substrate is heated using heat conduction of the energy. For this reason, much loss is generated in energy transmission, and excessive energy is required; as a result, it is difficult to carry out effective heat treatment. In addition, after annealing is completed, optical absorption films performing the function must be removed from the substrate. This is a factor of increasing the number of processes. If the process of removing these optical absorption films from the substrate is not properly carried out, films are left therein or over-etching takes place. This is a serious factor of reducing quality and reliability of products including the substrate.

On the contrary, according to the embodiment, Ge is ion-implanted to the entire surface of the silicon substrate 1 before heat treatment is subjected thereto. Ge is electrically inactive; therefore, almost no influence is given to electrical characteristic of other substances. The Ge ion implantation process is intactly applicable as pre-amorphous process when ion-implanting impurities to impurity diffusion regions. Namely, according to the embodiment, heat treatment is effectively carried out in the laser annealing process, and irradiation energy from light source is saved. In addition, it is possible to readily obtain proper profile of impurity contained in shallow impurity diffusion regions.

According to the embodiment, heat treatment using light beams is carried out without giving damages such as dislocation, defect, slip, crack, morphological degradation and fusion to the semiconductor substrate 1, regardless the kind of heating light source. Therefore, shallow impurity diffusion layers can be formed in the substrate 1 with high concentration. In addition, device characteristics provided on the substrate 1, that is, surface uniformity is improved, and device manufacture process is stabilized. Therefore, it is possible to readily manufacture micro MOS transistors, which can sufficiently show the performance of next-generation LSI.

According to one embodiment, electrically inactive Ge is ion-implanted to the entire surface of the silicon substrate 1 and various different materials provided thereon before heat treatment using light beams is carried out. In this case, there is almost no possibility that Ge gives influence to the conduction type and conductivity of the silicon substrate. By doing so, optical absorption coefficient is made approximately uniform in the surface layers of several films forming various device patterns without reducing electrical characteristics of the silicon substrate 1. As a result, it is possible to prevent non-uniform heating by dense and sparse mounting of various elements and thermal stress generated by non-uniform heating. In addition, optical absorption, that is, optical absorption efficiency of the surface layer of the semiconductor substrate 1 increases because electrically inactive impurities are doped. Thus, this serves to reduce irradiation energy of light source required for activating electrically inactive impurities. As a result, it is possible to reduce the possibility that thermal stress is generated in the semiconductor substrate 1, and to improve quality, reliability and production yield of semiconductor devices including the semiconductor substrate 1.

According to one embodiment, annealing is effectively carried out with respect to the semiconductor substrate 1, so that process window can be widened. In other words, it is possible to stabilize the manufacture process of semiconductor devices including heat treatment to the semiconductor substrate 1. Electrically inactive impurities are sufficiently activated to reduce electrical characteristic variations of semiconductor elements, so that the semiconductor elements can be readily micro-fabricated. Therefore, it is possible to manufacture CMOS transistors 20 having high performance, quality and reliability with high integration level.

In the semiconductor device according to the embodiment, the following effects are obtained. Namely, there is no possibility of generating deformation or damage by thermal stress and quality reduction by non-uniform heating in the semiconductor substrate included in the device. In addition, there is no reduction of electrical characteristics of semiconductor substrate and the like, so that quality, reliability and yield can be improved. According to the method of manufacturing the semiconductor device of the embodiment, the following effects are obtained. Namely, there is no possibility of generating electrical characteristic reduction of the semiconductor substrate, deformation or damage by thermal stress and quality reduction by non-uniform heating. Therefore, it is possible to readily manufacture a semiconductor device having improved quality, reliability and yield. In addition, high-quality shallow and deep source/drain diffusion layers 10, 11 and 18, 19 are effectively and readily formed. Therefore, it is possible to effectively and readily manufacture semiconductor devices, which include the CMOS transistor 20 having improved quality and reliability, and have improved yield.

The present invention is not limited to the semiconductor device and the method manufacturing the same described in one embodiment. Part of structure or process may be modified into various settings in the inventive range without departing from the spirit and scope of the invention. The structure or process may be carried out in the mode of being properly combined.

For example, in one embodiment described above, the substrate pre-heating temperature is set to about 400° C. to form deep source/drain diffusion layers 18 and 19. Under the condition that the irradiation energy density of the Xenon flash lamp is set to 35 J/cm², annealing is carried out to activate impurities. However, both substrate pre-heating temperature and irradiation energy density are not limited to the value described above. According to the experiment conducted by the inventors, the following matters are evident. Namely, the same effect as the foregoing embodiment is obtained even if any other settings are made so long as the substrate pre-heating temperature is set less than about 600° C. and the irradiation energy density is set less than 100 J/cm². In this case, the pulse width (light emitting time, irradiation time) of the flash lamp is not limited to about 1 ms. Even if any other values are set so long as the pulse width of the flash lamp is less than about 100 ms, the same effect as the foregoing embodiment is obtained.

According to the experiment conducted by the inventors, the following settings are made, and thereby, more preferable effects are obtained. According to the settings, the substrate pre-heating temperature is set within a range from about 200 to 500° C., and the irradiation energy density of the flash lamp is set within a range from about 10 to 60 J/cm². More specifically, the substrate pre-heating temperature is set to about 550° C. or less, and thereby, amorphous-state impurity implantation regions can be prevented from being incompletely crystallized before irradiation by the flash lamp. By doing so, it is possible to prevent residual defects from being generated in the impurity implantation regions. If the substrate pre-heating temperature is set to about 200° C. or less, irradiation energy density of 60 J/cm² or more is required to sufficiently activate impurities. This is a factor of easily generating damages by heat in the Si substrate. Thus, the substrate pre-heating temperature is set to about 200° C. or more, and thereby, it is possible to fully prevent the generation of damages by heat in the Si substrate. Under the condition, the irradiation energy density of the flash lamp is set within a range from about 10 to 60 J/cm². By doing so, it is possible to fully prevent the generation of damages by heat in the Si substrate, and to prevent degradation of the lifetime of the flash lamp.

Any forms other than the hot plate may be used to pre-heat the semiconductor substrate 1. Even if various heating lamps or laser beams are used, the same effect as the hot plate is obtained. In this case, hydrogen lamp, xenon lamp or halogen lamp may be used as the heating lamp.

Electrically inactive first impurity is ion-implanted to the entire surface of the silicon substrate 1 before electrically active second impurity (determining conduction type) is ion-implanted to the silicon substrate. The present invention is not limited to the above-mentioned ion implantation. For example, any other forms may be made so long as ion implantation is made before heat treatment for activating the second impurity is carried out. Namely, the first impurity is ion-implanted to the entire surface of the silicon substrate 1 after the second impurity is ion-implanted thereto. Even if such ion implantation is carried out, the same effect as the embodiment is obtained. The first impurity ion implantation is not limited to only one time per one-time heat treatment. Even if several-time ion implantations are carried out with respect to one-time heat treatment, the same effect as the embodiment is obtained. The first impurity is not limited to Ge. For example, at least one of group IV-B elements such as C, Si, Sn or Pb may be used as the electrically inactive first impurity. Even if such element is used, the same effect as the embodiment is obtained. For example, first impurity ion implantation is carried out several times. In this case, so long as at least one of group IV-B elements is used, the same effect as the embodiment is obtained even if the kind of impurity to be implanted is changed.

When ion-implanting electrically inactive first impurity to the silicon substrate 1, the concentration is not limited to the value 1×10¹⁹ cm⁻³ or more described before. The concentration may be set higher so long as the first impurity can make amorphous the surface layer of the silicon substrate 1. According to the experiment conducted by the inventors, the following matter is evident. Namely, when ion-implanting the first impurity to the silicon substrate 1, the concentration is set to 1×10²⁰ cm⁻³ or more, and thereby, the surface layer of the silicon substrate 1 is modified into a preferable amorphous state. Incidentally, when ion-implanting the first impurity to silicon substrate 1, the acceleration condition may be set to any other values so long as it is within a range having no reduction of leak characteristics of p-n junction.

In the embodiment, the CMOS transistor 20 is provided on the silicon substrate 1; however, the present invention is not limited to the embodiment. For example, only nMOS transistor 20a may be provided on the silicon substrate 1; in this case, there is no need of taking conduction type into consideration. Thus, electrically active impurities, that is, at least only one of group V-B elements such as As or P may be ion-implanted to the entire surface of the silicon substrate 1. In addition, only pMOS transistor 20a may be provided on the silicon substrate 1; in this also case, there is no need of taking conduction type into consideration. Thus, electrically active impurities, that is, at least one of group III-B elements such as B may be ion-implanted to the entire surface of the silicon substrate 1. As described above, there is no need of taking conduction type into consideration. Therefore, if the conduction type is the same, the same effect as the embodiment is obtained even if electrically active impurities are ion-implanted to the entire surface of the silicon substrate 1.

In the embodiment, the n-type impurity implanted to the nMOS region 1a is not limited to elements such as As and P. The same effect as the embodiment is obtained so long as at least one of group V-B elements is used as the n-type impurity. Likewise, the p-type impurity implanted to the pMOS region 1b is not limited to elements such as B. The same effect as the embodiment is obtained so long as at least one of group III-B elements is used as the n-type impurity.

Annealing process of forming shallow source/drain diffusion regions 10 and 11 is not limited to flash lamp annealing. The same effect as the embodiment is obtained even if RTA process using halogen lamp in place of the flash lamp is carried out. According to the experiment conducted by the inventors, it can be seen that the following annealing conditions is preferable when forming shallow source/drain diffusion regions 10 and 11. Namely, the substrate temperature is set to 900° C. or less, and heating time is set to 10 seconds or less, and thereby, high-quality diffusion regions 10 and 11 are obtained. This is based on the following reason. More specifically, the silicon substrate 1 is heated to high temperature for a short time, and thereby, impurity elements are activated without being diffused to deep position of the substrate 1. Thus, crystal defect is repaired in impurity regions 10 and 11.

In the embodiment, flash lamp annealing using Xenon flash lamp as the heating light source (annealer) is carried out. The present invention is not limited to the embodiment. For example, light sources of emitting light from the near infrared to ultraviolet range, such as mercury lamp, hydrogen lamp, metal halide lamp, rare gas lamp or YAG laser may be used the heating light source. Of course, the conventional halogen lamp may be used as the heating light source.

In the embodiment, shallow source/drain diffusion regions 10 and 11, that is, extension regions 10 and 11 and deep source/drain diffusion regions 18 and 19 are formed. The present invention is not limited to the embodiment. Of course, the present invention is sufficiently applicable to formation of channel regions or gate oxide films or other various heating processes requiring very short heating.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method of manufacturing a semiconductor device, comprising:
entirely implanting electrically inactive first impurity to one main surface of a semiconductor substrate; and
carrying out heat treatment by light with respect to the semiconductor substrate to which the first impurity is implanted.

2. The method according to claim 1, further comprising:
implanting electrically active second impurity having predetermined conduction type to the semiconductor substrate before the heat treatment is carried out; and
carrying out the heat treatment with respect to the semiconductor substrate to which the first and second impurities are implanted, and thereby, activating the second impurity.

3. The method according to claim 1, wherein the first impurity is ion-implanted to the surface layer of the semiconductor substrate at concentration of 1×10¹⁹ cm⁻³ or more.

4. The method according to claim 1, wherein at least one of group IV-B elements is sued as the first impurity.

5. The method according to claim 1, further comprising:
pre-heating the semiconductor substrate to predetermined temperature of 600° C. or less before the heat treatment is carried out with respect thereto; and
carrying out the heat treatment with respect to the semiconductor substrate after pre-heating is made, said pre-heating being flash lamp annealing carried out under conditions that light emitting time is 100 msec or less and irradiation energy density is 100 J/cm² or less.

6. The method according to claim 4, wherein at least one of C, Si, Ge, Sn and Pb is used as the first impurity.

7. The method according to claim 5, further comprising:
carrying out said pre-heating to the semiconductor substrate using at least one of hot plate, heating lamp and laser beams.

8. The method according to claim 5, further comprising:
using any of hydrogen lamp, xenon lamp and halogen lamp as the heating lamp.

9. A method of manufacturing a semiconductor device, comprising:
providing a gate electrode having a gate insulating film on one main surface of a semiconductor substrate;
entirely implanting electrically inactive first impurity to one main surface of the semiconductor substrate provided with the gate electrode while implanting electrically active second impurity having predetermined conduction type to the semiconductor substrate to a region adjacent to the gate electrode of the semiconductor substrate using the gate electrode as a mask;
forming shallow source/drain diffusion regions having the predetermined conduction type, the shallow source/drain diffusion regions being formed in a manner that heating treatment using light is carried out the semiconductor substrate to which the first and second impurities are implanted, and thereby, the second impurity is activated;
providing a gate sidewall film around the gate electrode;
entirely implanting the first impurity to one main surface of the semiconductor substrate provided with the gate sidewall film while implanting the second impurity to the semiconductor substrate to a region adjacent to the gate sidewall film of the semiconductor substrate using the gate electrode and the gate sidewall film as a mask; and
forming deep source/drain diffusion regions having the predetermined conduction type, and continuing with the shallow source/drain diffusion regions, the deep source/drain diffusion regions being formed in a manner that the heating treatment is carried out the semiconductor substrate to which the first and second impurities are implanted, and thereby, the second impurity is activated.

10. The method according to claim 9, wherein the first impurity is ion-implanted to the surface layer of the semiconductor substrate at concentration of 1×10¹⁹ cm⁻³ or more.

11. The method according to claim 9, wherein at least one of group IV-B elements is sued as the first impurity.

12. The method according to claim 9, further comprising:
pre-heating the semiconductor substrate to predetermined temperature of 600° C. or less before the heat treatment is carried out with respect thereto; and
carrying out the heat treatment with respect to the semiconductor substrate after pre-heating is made, said pre-heating being flash lamp annealing carried out under conditions that light emitting time is 100 msec or less and irradiation energy density is 100 J/cm² or less.

13. The method according to claim 11, wherein at least one of C, Si, Ge, Sn and Pb is used as the first impurity.

14. The method according to claim 12, further comprising:
carrying out said pre-heating to the semiconductor substrate using at least one of hot plate, heating lamp and laser beams.

15. The method according to claim 14, further comprising:
using any of hydrogen lamp, xenon lamp and halogen lamp as the heating lamp.

16. A semiconductor device comprising:
a semiconductor substrate subjected to heat treatment using light after electrically inactive first impurity is entirely implanted.

17. The device according to claim 16, further comprising:
the semiconductor substrate to which electrically active second impurity having predetermined conduction type is implanted, and the semiconductor substrate being subjected to the heat treatment so that the second impurity is activated after the first and second impurities are implanted.

18. The device according to claim 16, wherein the first impurity is ion-implanted to the surface layer of the semiconductor substrate at concentration of 1×10¹⁹ cm⁻³ or more.

19. The device according to claim 16, wherein at least one of group IV-B elements is sued as the first impurity.

20. The device according to claim 19, wherein at least one of C, Si, Ge, Sn and Pb is used as the first impurity.

21. A semiconductor device comprising:
a semiconductor substrate formed with source/drain diffusion regions having predetermined conduction type, the semiconductor substrate being subjected to the following treatment such that electrically inactive first impurity is entirely implanted to the semiconductor substrate while electrically active second impurity having predetermined conduction type being implanted thereto, and the source/drain diffusion regions being formed in a manner that heating treatment using light is carried out the semiconductor substrate to which the first and second impurities are implanted, and thereby, the second impurity is activated; and
a gate electrode provided on the source/drain diffusion regions, and having a gate insulating film and a gate sidewall film.

22. The device according to claim 21, wherein the first impurity is ion-implanted to the surface layer of the semiconductor substrate at concentration of 1×10¹⁹ cm⁻³ or more.

23. The device according to claim 21 wherein at least one of group IV-B elements is sued as the first impurity.

24. The device according to claim 23, wherein at least one of C, Si, Ge, Sn and Pb is used as the first impurity.
